(19) United States
(12) Patent Application Publication
(10) Pub. No.: US 2025/0392322 A1
(43) Pub. Date: Dec. 25, 2025

(54) DIFFERENTIAL DIGITAL-TO-ANALOG CONVERTER

(71) Applicant: TEXAS INSTRUMENTS INCORPORATED, Dallas, TX (US)

(72) Inventors: Prakhar Agrawal, Bangalore (IN); Meghna Agrawal, Bangalore (IN)

(21) Appl. No.: 18/750,461

(22) Filed: Jun. 21, 2024

(51) Int. Cl. H03M 1/78

(52) U.S. Cl. CPC H03M 1/785

(57) ABSTRACT

Embodiments disclosed herein relate to digital-to-analog converters (DACs), and more particularly, to architecture thereof for improving bit resolution of the DACs. In an embodiment, a circuit is provided that includes a first DAC sub-circuit, a second DAC sub-circuit, and a control circuit coupled to control the first and second DAC sub-circuits. The first DAC sub-circuit includes a first set of transistors and a first set of switches coupled to the first set of transistors and to output nodes. The second DAC sub-circuit includes a second set of transistors coupled to the first set of transistors and a second set of switches coupled to the second set of transistors and to the output nodes.

### TECHNICAL FIELD

This relates generally to digital-analog-converters (DACs), and more particularly, to architecture thereof.

### BACKGROUND

In digital-to-analog converter (DAC) circuits, various transistors, switches, digital logic circuits, and the like can be included to receive digital input signals and convert the digital input signals to analog output signals for use by one or more downstream systems and circuits. A differential DAC may include such components to form an interface between digital data processing circuits and an analog front-end of a transmitter device. The differential DAC may receive digital input signals from a digital system or circuit, convert the digital input signals to differential analog output signals, and provide the analog output signals to a transmitter device for transmission, among other use.

As digital system functionality increases in complexity, individual standard cell area optimization for digital circuits, such as flip-flops, latches, transistors, and switches, becomes increasingly critical. Often, existing DAC systems include transistors and switches for purposes other than improving resolution of converted outputs, such as improving linearity and/or reducing noise, which consume design area. To increase resolution of existing DAC systems, the number of circuit elements in a DAC can be increased and scaled accordingly across different subsystems of the DAC systems. However, increasing the number of circuit elements in the DAC systems comes at a cost of additional area and current.

### SUMMARY

Various embodiments disclosed herein relate to digital-to-analog converters (DACs), and more particularly, to architecture thereof for improving bit resolution of the DACs. In an example embodiment, a circuit is provided that includes a first DAC sub-circuit, a second DAC sub-circuit coupled to the first DAC sub-circuit, and a set of driver circuits coupled to control switches of the first DAC sub-circuit and the second DAC sub-circuit. The first DAC sub-circuit includes a first transistor coupled to a power supply node, a first switch coupled to the first transistor and to a first output node, a second switch coupled to the first transistor and to a second output node, a second transistor coupled to the power supply node, a third switch coupled to the second transistor and to the first output node, and a fourth switch coupled to the second transistor and to the second output node. The second DAC sub-circuit includes a third transistor coupled to the power supply node, a fifth switch coupled to the third transistor and coupled to the first output node, a sixth switch coupled to the third transistor and coupled to the second output node, a fourth transistor coupled to the power supply node, a seventh switch coupled to the fourth transistor and to the first output node, and an eighth switch coupled to the fourth transistor and to a ground node.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example digital-to-analog converter (DAC) circuit in accordance with an embodiment.

FIG. 2 illustrates example resolution results of a DAC circuit in accordance with an embodiment.

FIG. 3 illustrates an example digital-to-analog converter (DAC) circuit in accordance with an embodiment.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Discussed herein are enhanced components, systems, and architectures related to digital-to-analog converters (DACs), and more particularly, to improving bit resolution of the DACs. In a DAC, various numbers of bit-resolution arms may be included to produce differential analog signals. The arms of a DAC may each include a set of switches and a set of transistors coupled in series between the set of switches and a power rail. A first switch of a given arm may be configured to contribute to the voltage at a positive output, and a second switch of the arm may be configured to contribute to the voltage at a negative output. The switches may further be coupled to digital logic circuitry configured to control the states of the switches based on one or more bits of a digital value. In other words, the digital logic circuitry may open one switch and close the other switch, such that when current from the transistors flows through the closed switch, an output is fed to an output node. The topology of the arms and the control thereof via the digital logic circuitry may determine the resolution of the DAC.

In existing DACs, one or more arms of a DAC might not be directly used in the conversion of a digital value to an analog voltage at the outputs, or in other words, might not be controlled by the digital value itself. In such examples, an arm may go unused based on an amount of other circuitry and logic required to operate the unused arm. Additionally, operating an unused arm in the DAC may present issues related to linearity and noise, which may be avoided by grounding the arm.

Instead, as disclosed herein, example topologies of DACs are described that include an arm used as a single-ended current pump to increase resolution, and in some examples, to provide the linearity and noise improvements of a grounded arm. More specifically, an arm may include a first transistor, a second transistor coupled to the first transistor, and two switches coupled to the second transistor. A first switch may be coupled to an output node, and a second switch may be coupled to a ground node. Thus, as current flows through the first and second transistors and through the first switch, an output may be provided to the output node. However, as current flows through the first and second transistors when the first switch is open and the second switch is closed, current might not flow through the second switch to an output node, as the second switch is grounded. Thus, an additional bit of resolution may be achieved based on using the arm in this topology. Advantageously, such a topology may not only increase resolution of the DAC but also decrease cost, area, and current consumption of the DAC relative to a DAC having resolution equal to the increased resolution of the DAC using this topology. For example, an 11-bit DAC using the topology may produce 12 bits of resolution with lower area and cost requirements as a 12-bit DAC.

In an embodiment, a circuit is provided that includes a first DAC sub-circuit, a second DAC sub-circuit coupled to the first DAC sub-circuit, and a control circuit coupled to control switches of the first DAC sub-circuit and the second DAC sub-circuit. The first DAC sub-circuit includes a first transistor coupled to a power supply node, a first switch coupled to the first transistor and to a first output node, a second switch coupled to the first transistor and to a second output node, a second transistor coupled to the power supply node, a third switch coupled to the second transistor and to the first output node, and a fourth switch coupled to the second transistor and to the second output node. The second DAC sub-circuit includes a third transistor coupled to the power supply node, a fifth switch coupled to the third transistor and coupled to the first output node, a sixth switch coupled to the third transistor and coupled to the second output node, a fourth transistor coupled to the power supply node, a seventh switch coupled to the fourth transistor and to the first output node, and an eighth switch coupled to the fourth transistor and to a ground node.

In another example embodiment, a circuit is provided. The circuit includes a set of driver circuits coupled to receive a set of digital signals representing a digital value, a first DAC sub-circuit coupled to a first subset of the set of driver circuits, a second DAC sub-circuit coupled to the first DAC sub-circuit and coupled to a second subset of the set of driver circuits, and a third DAC sub-circuit coupled to the first and second DAC sub-circuits and coupled to a third subset of the set of driver circuits. The first DAC sub-circuit includes a first set of transistors and a first set of switches coupled to the first set of transistors. The second DAC sub-circuit includes a second set of transistors and a second set of switches coupled to the second set of transistors. The third DAC sub-circuit includes a transistor, a first switch coupled to the transistor, and a second switch coupled to the transistor. The first subset of the set of driver circuits includes a first decoder coupled to receive a first subset of the set of digital signals and is configured to provide the first subset of the set of digital signals to the first set of switches. The second subset of the set of driver circuits includes a second decoder coupled to receive a second subset of the set of digital signals and is configured to provide the second subset of the set of digital signals to the second set of switches. The third subset of the set of driver circuits is coupled to receive a third subset of the set of digital signals and is configured to provide the third subset of the set of digital signals to first switch of the third DAC sub-circuit. The first, second, and third DAC sub-circuits are configured to output signals, based on the first, second, and third subsets of the digital signals, respectively, at a first output node and at a second output node.

In yet another example embodiment, a circuit is provided that includes a first DAC sub-circuit, a second DAC sub-circuit coupled to the first DAC sub-circuit, and a set of driver circuits coupled to control switches of the first and second DAC sub-circuits. The first DAC sub-circuit includes a first transistor coupled to a power supply, a second transistor coupled to a first ground node, a first switch coupled to the first transistor, a second switch coupled to the first switch and to the second transistor, a third switch coupled to the first transistor, a fourth switch coupled to the third switch and to the second transistor, a third transistor coupled to the power supply, a fourth transistor coupled to a second ground node, a fifth switch coupled to the third transistor, a sixth switch coupled to the fifth switch and to the fourth transistor, a seventh switch coupled to the third transistor, and an eighth switch coupled to the seventh switch and to the fourth transistor. The second DAC sub-circuit includes a fifth transistor coupled to the first DAC sub-circuit and to the power supply, a sixth transistor coupled to a third ground node, a ninth switch coupled to the fifth transistor, a tenth switch coupled to the ninth switch and to the sixth transistor, an eleventh switch coupled to the fifth transistor, and a twelfth switch coupled to the eleventh switch and to the sixth transistor. The first and second switches, the fifth and sixth switches, and the ninth and tenth switches are coupled to a first output node. The third and fourth switches, the seventh and eighth switches, and the eleventh and twelfth switches are coupled to a second output node.

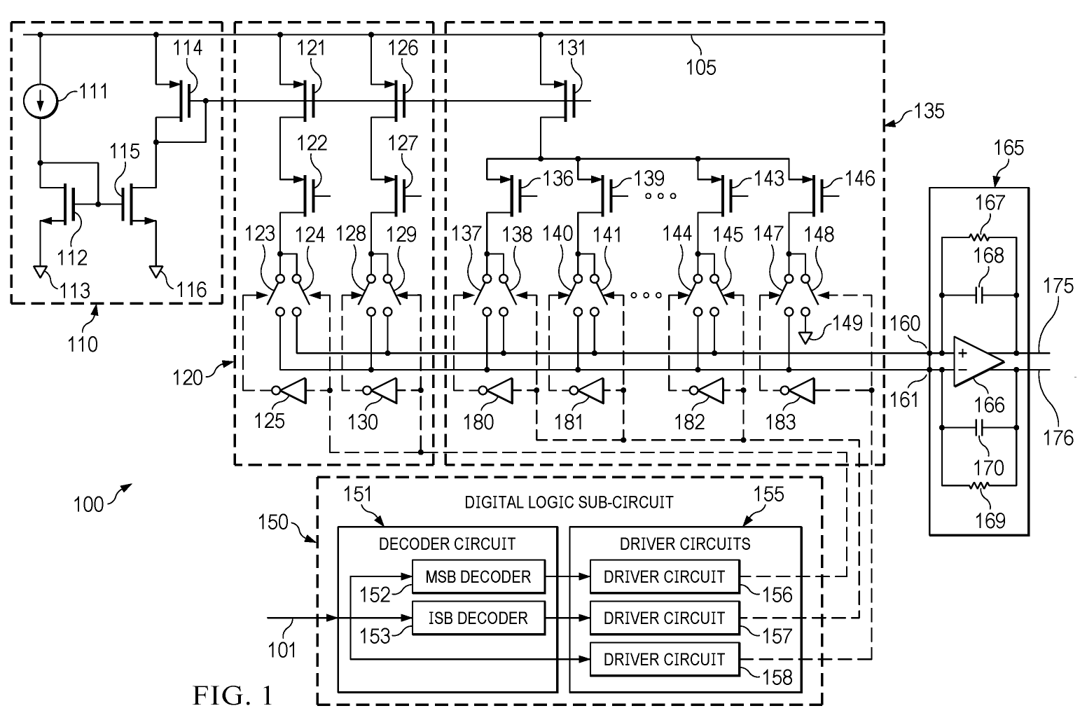

FIG. 1 illustrates an example digital-to-analog converter (DAC) circuit in accordance with an embodiment. FIG. 1 shows circuit 100, which includes bias sub-circuit 110, DAC sub-circuit 120, DAC sub-circuit 135, control circuit 150, and filter sub-circuit 165.

In various examples, circuit 100 is representative of an integrated circuit or system-on-chip (SoC) that includes various hardware elements and circuitry configured to receive digital input signals 101 that specify a digital value, convert the digital input signals 101 into a voltage between the differential analog outputs 175 and 176 based on the digital value, and provide the voltage across analog outputs 175 and 176 downstream to other circuits and subsystems. For example, circuit 100 may be representative of a thermometric DAC. In some examples, circuit 100 may be representative of another type of DAC.

Circuit 100 includes control circuit 150 coupled to receive the digital input signals 101 and filter sub-circuit 165 coupled to provide the voltage across analog outputs 175 and 176 downstream. Circuit 100 also includes bias sub-circuit 110, DAC sub-circuit 120, and DAC sub-circuit 135 to convert ones of the digital input signals 101 based on control provided by control circuit 150 and to provide converted values of the digital input signals 101 to filter sub-circuit 165.

Bias sub-circuit 110 may be representative of a circuit capable of receiving power from power supply node 105, generating a gate bias voltage for producing a fixed current among DAC sub-circuits 120 and 135, and providing the gate bias voltage to DAC sub-circuits 120 and 135. More specifically, bias sub-circuit 110 may provide a voltage operating point to bias transistors of DAC sub-circuits 120 and/or 135 (e.g., bias transistors 121, 126, and 131) at gate terminals of the respective transistors. Bias sub-circuit 110 may include transistor 112, transistor 114, and transistor 115 that each include a gate terminal, a source terminal, and a drain terminal. The drain terminal of transistor 112 may be coupled to receive bias current 111 from power supply node 105 and may be coupled to the gate terminal of transistor 112, the gate terminal of transistor 115, and to elements of DAC sub-circuit 120. The source terminal of transistor 112 may be coupled to ground node 113. The source terminal of transistor 114 may also be coupled to power supply node 105 and to elements of DAC sub-circuit 120. The gate terminal of transistor 114 may be coupled to the drain terminal of transistor 114 and to elements of DAC sub-circuit 120. More specifically, the gate terminal of transistor 114 may be coupled to provide a voltage bias to gate terminals of transistors of DAC sub-circuit 120, such as transistors 121, 126, and 131. The drain terminal of transistor 114 may be coupled to the drain terminal of transistor 115. The source terminal of transistor 115 may be coupled to ground node 116.

DAC sub-circuit 120 may be representative of a circuit capable of affecting the voltages of outputs 160 and 161 based on most-significant bit (MSB) values of the digital value of the digital input signals 101 provided to DAC sub-circuit 120 under the control of control circuit 150. DAC sub-circuit 120 may include a number of MSB arms (e.g., 2^{k} MSB arms), each of which may include a set of transistors and a set of switches. A switch may be implemented by using one or more transistors (e.g., a set of transistors coupled in parallel) coupled between terminals of the switch to control the flow of current between the terminals. In circuit 100, DAC sub-circuit 120 includes two MSB arms. The first MSB arm includes bias transistor 121, transistor 122, switch 123, and switch 124. The second MSB arm includes bias transistor 126, transistor 127, switch 128, and switch 129. Each of the source terminals of bias transistors 121, 126, and 131 may be coupled together and coupled to power supply node 105. Additionally, each of the gate terminals of bias transistors 121, 126, and 131 may be coupled to the gate terminal of transistor 114. The drain terminal of transistor 121 may be coupled to the source terminal of transistor 122. The drain terminal of transistor 126 may be coupled to the source terminal of transistor 127. The drain terminal of transistor 131 may be coupled to elements of DAC sub-circuit 135, or more specifically, to source terminals of transistors thereof. The gate terminals of transistors 122 and 127 may be coupled to bias voltage generation circuits (e.g., mirror circuits) to receive a cascode bias voltage. The drain terminal of transistor 122 may be coupled to a first terminal of switch 123 and to a first terminal of switch 124. The drain terminal of transistor 127 may be coupled to a first terminal of switch 128 and to a first terminal of switch 129. A second terminal of switch 123 may be coupled to output 161. A second terminal of switch 124 may be coupled to output 161. A first terminal of switch 128 may be coupled to output 161. A second terminal of switch 129 may be coupled to output 160.

Each of the switches 123, 124, 128, and 129 may be controlled by the set of MSBs of the digital value of the digital input signals 101. Accordingly, the control circuit 150 may include an MSB decoder 152 configured to receive at least a portion of the digital input signals 101 and to generate a first set of control signals based on the set of most significant bits. The control circuit 150 may also include a driver circuit 156 coupled to the MSB decoder 152 and configured to generate a second set of control signals based on the first set of control signals and to provide the second set of control signals to the switches 123, 124, 128, and 129. In an example, a first control signal of the second set is provided to a control terminal of switch 124 and to an inverter 125 coupled to a control terminal of switch 123. In the example, a second control signal of the second set is provided to a control terminal of switch 129 and to an inverter 130 coupled to a control terminal of switch 128.

DAC sub-circuit 135 may be representative of a circuit capable of receiving and resolving intermediately-significant bit (ISB) values of the digital input signals 101 provided to DAC sub-circuit 135 by control circuit 150. DAC sub-circuit 135 may include a number of ISB arms (e.g., 2^{p}-1 ISB arms), each of which may include a set of transistors and a set of switches. In circuit 100, DAC sub-circuit 135 includes four ISB arms as well as transistor 131 coupled to each of the ISB arms, to power supply node 105, and to DAC sub-circuit 120. A first ISB arm includes transistor 136, switch 137, and switch 138. A second ISB arm includes transistor 139, switch 140, and switch 141. A third ISB arm includes transistor 143, switch 144, and switch 145. An ISB arm includes transistor 146, switch 147, and switch 148. The source terminals of transistors 136, 139, 143, and 146 may be coupled to the drain terminal of transistor 131. The gate terminals of transistors 136, 139, 143, and 146 may be coupled to bias voltage generation circuits to receive a cascode bias voltage. The drain terminal of transistor 136 may be coupled to a first terminal of switch 137 and to a first terminal of switch 138. The drain terminal of transistor 139 may be coupled to a first terminal of switch 140 and to a first terminal of switch 141. The drain terminal of transistor 143 may be coupled to a first terminal of switch 144 and to a first terminal of switch 145. The drain terminal of transistor 146 may be coupled to a first terminal of switch 147 and to a first terminal of switch 148. A second terminal of switch 137 may be coupled to output 161, and a second terminal of switch 138 may be coupled to output 160. A second terminal of switch 140 may be coupled to output 161. A second terminal of switch 141 may be coupled to output 160. A second terminal of switch 144 may be coupled to output 161, and a second terminal of switch 145 may be coupled to output 160. A second terminal of switch 147 may be coupled to output 161. A second terminal of switch 148 may be coupled to ground node 149.

Each of the switches 137, 138, 140, 141, 144, and 145 may be controlled by the set of ISBs of the digital value of the digital input signals 101. Accordingly, the control circuit 150 may include an ISB decoder 153 configured to receive at least a portion of the digital input signals 101 and to generate a first set of control signals based on the set of most significant bits. The control circuit 150 may also include a driver circuit 157 coupled to the ISB decoder 153 and configured to generate a second set of control signals based on the first set of control signals and to provide the second set of control signals to the switches 137, 138, 140, 141, 144, and 145. In an example, a first control signal of the second set is provided to a control terminal of switch 138 and to an inverter 180 coupled to a control terminal of switch 137. In the example, a second control signal of the second set is provided to a control terminal of switch 141 and to an inverter 181 coupled to a control terminal of switch 140. Continuing the example, a third control signal of the second set is provided to a control terminal of switch 145 and to an inverter 182 coupled to a control terminal of switch 144.

Switches 147 and 148 may be controlled by the ISB of the digital value of the digital input signals 101. Accordingly, the control circuit 150 may include a driver circuit 158 coupled to receive the ISB of the digital input signals 101 and configured to generate a control signal based on the ISB of the digital input signals 101 and to provide the control signal to the switches 147 and 148. In an example, the control signal is provided to a control terminal of switch 148 and to an inverter 183 coupled to a control terminal of switch 147.

Filter sub-circuit 165 may be representative of various hardware components coupled to receive signals from DAC sub-circuits 120 and 135 at outputs 160 and 161 and output analog output signal across outputs 175 and 176 at outputs of filter sub-circuit 165. Filter sub-circuit 165 may include operational amplifier 166 (i.e., a differential operational amplifier (OpAmp)), resistor 167, capacitor 168, resistor 169, and capacitor 170. Operational amplifier 166 includes two inputs and two outputs to produce differential analog outputs. A positive input of operational amplifier 166 is coupled to output 160 and to first terminals of resistor 167 and capacitor 168. A first output of operational amplifier 166 is coupled to second terminals of resistor 167 and capacitor 168 and coupled to output analog output signal 175. A negative input of operational amplifier 166 is coupled to output 161 and to first terminals of resistor 169 and capacitor 170. A second output of operational amplifier 166 is coupled to second terminals of resistor 169 and capacitor 170 and coupled to output analog output signal 176. Resistor 167 and capacitor 168 may be coupled together in parallel and may form a first resistor-capacitor (RC) circuit of filter sub-circuit 165. Resistor 169 and capacitor 170 may be coupled together in parallel and may form a second RC circuit of filter sub-circuit 165.

Control circuit 150 may be representative of various components configured to receive digital input signals 101, decode the digital input signals 101, and control switches of DAC sub-circuits 120 and 135 based on the digital input signals 101. Control circuit 150 includes decoder circuit 151 and digital circuits 155. Decoder circuit 151 includes a first decoder, MSB decoder 152, and a second decoder, ISB decoder 153. Digital circuits 155 includes driver circuits 156, 157, and 158. MSB decoder 152 may be coupled to receive a first set of digital input signals of digital input signals 101, and ISB decoder 153 may be coupled to receive a second set of digital input signals of digital input signals 101. MSB decoder 152 may include a number of outputs corresponding to the number of MSB arms of DAC sub-circuit 120 (e.g., from k input lines to 2^{k} output lines). The outputs of MSB decoder 152 may be coupled to driver circuit 156. Similarly, ISB decoder 153 may include a number of outputs corresponding to the number of ISB arms of DAC sub-circuit 135 (e.g., from p input lines to 2^{p}-1 output lines). The outputs of ISB decoder 153 may be coupled to driver circuit 157.

Driver circuits 156, 157, and 158 may include various circuits and devices coupled to receive sets of digital input signals 101 from decoder circuit 151 and coupled to control switches of DAC sub-circuits 120 and 135. For example, driver circuits 156, 157, and 158 include a number of flip-flop circuits, a number of level shifters, and a number of buffers. The flip-flop circuits of driver circuit 156 may be coupled to the outputs of MSB decoder 152 and may be configured to store state data of the set of digital input signals 101 provided by MSB decoder 152, provide timing alignment among digital circuits 155, provide the set of digital input signals 101 to the level shifters. The level shifters may be configured to increase or decrease a supply voltage, such as from a core supply voltage (e.g., 1.1 V) to an analog supply voltage (e.g., 1.3 V). The buffers may be configured to output digital input signals 101 to switches of DAC sub-circuit 120 for control thereof. The number of flip-flop circuits, level shifters, and buffers of driver circuit 156 may be based on the number of MSB arms of DAC sub-circuit 120. The flip-flop circuits of digital circuits 157 may be coupled to the outputs of ISB decoder 153 and may be configured to store state data of the set of digital input signals 101 provided by ISB decoder 153, provide timing alignment among digital circuits 155, provide the set of digital input signals 101 to the level shifters. The level shifters may be configured to increase or decrease a supply voltage, such as from a core supply voltage (e.g., 1.1 V) to an analog supply voltage (e.g., 1.3 V). The buffers may be configured to output digital input signals 101 to switches of DAC sub-circuit 135 for control thereof. The number of flip-flop circuits, level shifters, and buffers of digital circuits 157 may be based on the number of ISB arms of DAC sub-circuit 135. Digital circuits 158 may be coupled to receive a third set of digital input signals of digital input signals 101 directly from a digital source as opposed to receiving the set of signals from a decoder of decoder circuit 151. In various examples, digital circuits 158 includes a single flip-flop circuit, level shifter, and buffer coupled to control switch 147 of DAC sub-circuit 135.

In various examples, the first set of digital input signals may include signals from k+p to p+1 (i.e., total k lines), the second set of digital input signals may include signals from p to 1 (i.e., total p lines), and the third set of digital input signals may include signal 0 (i.e., 1 line) of digital input signals 101. In some examples, other combinations or variations of digital input signals 101 may be provided to decoder circuit 151 and decoders thereof.

By way of example, circuit 100 may be representative of a 12-bit DAC configured to receive and convert digital input signals 101 including <11:0> digital lines as the input to decoder circuit 151. MSB decoder 152 may include 128 digital lines (i.e., 2⁷), which may be coupled to 128 flip-flops of digital circuits 156 for timing alignment. The 128 flip-flop outputs may be coupled to 128 level shifters for changing the supply voltage from core supply (~1.1V) to analog supply (~1.3V). The 128 level shifter outputs may be coupled to 128 buffers. The buffer outputs may be divided into two parallel paths. One path may directly control switches 124 and 129 (i.e., second switches of each MSB arm) and another path may be coupled to 128 logic gates (e.g., inverters) (e.g., logic gate 125). Each logic gate may be coupled to a first switch of the MSB arms to control the switches. A similar topology and control scheme exists between ISB decoder 153, digital circuits 157, and switches of DAC sub-circuit 135.

Based on being controlled by control circuit 150, the switches of DAC sub-circuits 120 and 135 may provide differential signals at outputs 160 and 161. More specifically, first switches may provide a positive analog voltage at output 161, and second switches may provide a negative analog voltage at output 160. Filter sub-circuit 165 receives the differential signals at outputs 160 and 161 and performs filtering, via operational amplifier 166 and the two RC circuits of filter sub-circuit 165, on the differential signals to determine an analog output signal at outputs 175 and 176.

In circuit 100, an intermediately-significant bit (ISB) arm of DAC sub-circuit 135 that includes transistor 146, switch 147, and switch 148 may provide an additional bit of resolution for analog output signal across outputs 175 and 176 based on the control of switch 147 via digital circuits 158 and based on switch 148 being grounded at ground node 149. In other words, transistor 146 may be used as a single-ended current pump. In some examples, a diode may further be coupled between switch 148 and ground node 149. In previous solutions, this sub-circuit of DAC sub-circuit 135 may be unused due to logic and component scaling required to control transistor 146 and switches 147 and 148. Thus, advantageously, without adding additional MSB arms, ISB arms, or least-significant bit (LSB) arms to account for this sub-circuit, such a topology may reduce the amount of area, power, and cost required to provide increased resolution with fewer components relative to a higher resolution solution.

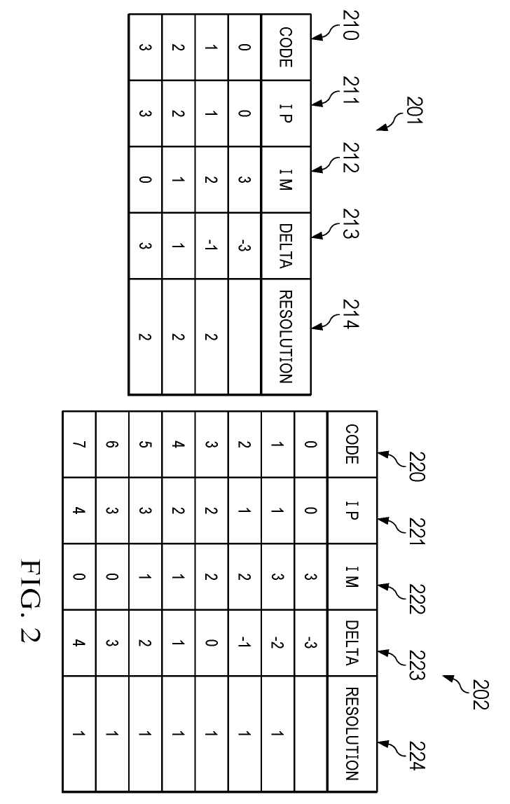

FIG. 2 illustrates example resolution results of a DAC circuit in accordance with an embodiment. FIG. 2 includes tables 201 and 202. Table 201 represents a first mode of operation of a circuit, such as circuit 100, in which an ISB arm is coupled to ground independent of the digital value, while table 202 represents a second mode of operation of the circuit with a relatively higher resolution through the use of the ISB arm as a single-ended current pump governed by the digital value.

In tables 201 and 202, the tables include values corresponding to code 210, current 211, current 212, a difference between current 211 and current 212 (delta 213), and resolution 214. The values may correspond to a unit as opposed to actual measurements of current. Code 210 may refer to digital values of the digital input signals 101, and in the illustrated example, the digital input signals include 1 MSB, 1 ISB, and, due to the first mode of operation, an unused ISB. Thus, code 210 has 4 possible values. It should be understood that other examples may have any number of MSBs and/or ISBs.

In this way code 210 may refer to a number of control changes to switches of an arm of a DAC sub-circuit. By way of example, an arm may refer to a subset of a DAC sub-circuit, such as DAC sub-circuit 135, that includes a set of transistors (e.g., transistors 136 and 139) and a set of switches (e.g., switches 137 and 138). In operation, a first switch of an arm of a DAC sub-circuit may be open at a given time while the second switch of the arm may be closed. The switches can change states such that the first switch is closed, and the second switch is open based on controls from digital logic circuitry (e.g., digital circuits 155 of control circuit 150). Resolution 214 may refer to a resolution with which values are resolved and converted from digital to analog via the DAC sub-circuit. The smaller the value of resolution 214, the finer the resolution.

Referring first to table 201, for code 210 of zero, or in other words no switching of the switches of the arms of a DAC sub-circuit, zero units of current 211 may flow through positive switch(es) (e.g., switches 123, 128, 137, 140, 144, etc.), while three units of current 212 may flow through negative switch(es) (e.g., switches 124, 129, 138, 141, 145, etc.). In the first mode of operation, switch 147 may be open and switch 148 may be closed. Accordingly, delta 213 between current 211 and 212 is negative three (-3). There might not be a value of resolution 214 when code 210 has a value of zero. In some examples, this value may be used as reference for calculating resolution 214 for other code changes. For code 210 of one, or in other words for a single change in states between the two switches of an arm, one unit of current 211 may flow through the positive switch(es), while two units of current 212 may flow through the negative switch. Thus, delta 213 may include a value of negative one (-1). In such solutions involving conventional DACs, resolution 214 may be computed as the difference between the value of delta 213 when code 210 is 0 (i.e., -3) and the value of delta 213 when code 210 is 1 (i.e., -1). Thus, in this scenario, resolution 214 may include a value of two. Similar outcomes with respect to resolution 214 may be determined using code 210 of 2 and 3. It follows that the finest value of resolution 214 for an existing DAC solution may be two.

Next, referring to table 202, table 202 includes results corresponding to operation of the DAC in a second mode that uses a single-ended current pump transistor to provide finer resolution. Code 220 may refer to digital values of the digital input signals 101, and in the illustrated example, the digital input signals include 1 MSB, 1 ISB, and, due to the second mode of operation, 1 ISB. Thus, code 220 has 8 possible values. It should be understood that other examples may have any number of MSBs and/or ISBs.

In operation, as the states of switches of each arm of circuit 100 are changed from open to closed and closed to open, different units of current may flow through each positive and negative switch. However, the second mode of operation, the ISB controls the switching of switch 147 that may affect the voltage at output 161 based on the ISB, and likewise the ISB controls the switching of switch 148 that is coupled to ground node 149. In this way, when switch 147 is closed and switch 148 is open, current may flow through switch 147 to output 161, but when switch 147 is open and switch 148 is closed, current flows through switch 148 to ground node 149, but no current flows into filter sub-circuit 165 through switch 148 unlike other sub-circuits of DAC sub-circuit 135. Thus, an additional half bit of resolution may be achieved using such a topology. For example, for code 220 of one, one unit of current 221 may flow through positive switch(es) of DAC sub-circuit 135 of circuit 100 (e.g., switches 137, 140, 144, and 147) and three units of current 222 may flow through negative switches of DAC sub-circuit 135 of circuit 100 (e.g., switches 138, 141, and 145). Delta 213 between current 221 and current 222 may include a value of negative two (-2), however, due to the lack of current flow through negative switch(es) 148, resolution 224 may include a value of one. Similar values of resolution 224 may be determined using other numbers of code 220. It follows that values of resolution 224 may be finer using a topology as shown in circuit 100 relative to existing DAC topologies that do not include a single-ended current pump transistor.

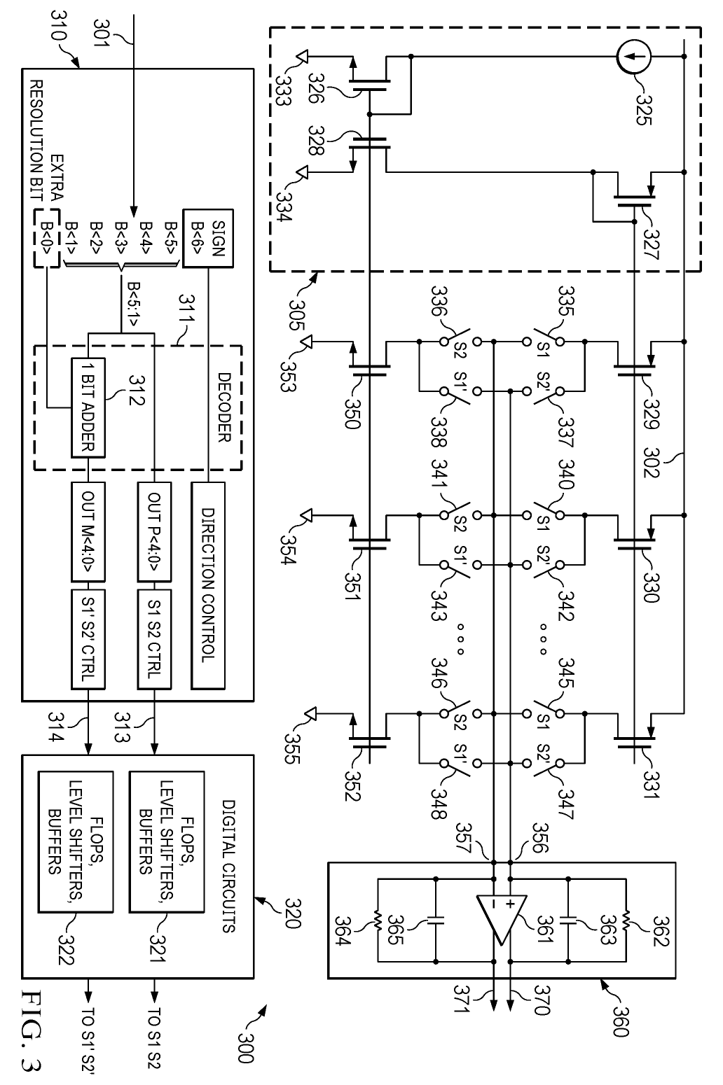

FIG. 3 illustrates an example digital-to-analog converter (DAC) circuit in accordance with an embodiment. FIG. 3 shows circuit 300, which includes bias sub-circuit 305, decoder sub-circuit 310, control sub-circuit 320, filter sub-circuit 360, and various transistors and switches coupled thereto.

In various examples, circuit 300 is representative of an integrated circuit or system-on-chip (SoC) that includes various hardware elements and circuitry configured to receive digital input signals 301, convert the digital input signals 301 into differential analog output signals 370 and 371, and provide the analog output signals 371 downstream to other circuits and subsystems. For example, circuit 300 may be representative of a binary weighted DAC. In some examples, circuit 300 may be representative of another type of DAC.

Circuit 300 includes decoder subsystem 310 coupled to receive the digital input signals 301, digital circuits 320 coupled to control switches of circuit 300 based on the digital input signals 301, and filter sub-circuit 360 coupled to provide the analog output signals 370 and 371 downstream. Circuit 300 also includes bias sub-circuit 305 and a number of arms including sets of transistors and sets of switches configured to convert ones of the digital input signals 301 based on control provided by digital circuits 320 and configured to provide converted values of the digital input signals 301 to filter sub-circuit 360.

Bias sub-circuit 305 may be representative of a circuit capable of receiving power from power supply 302, generating a gate bias voltage for producing a fixed current among sub-circuits of circuit 300, and providing the gate bias voltage to the sets of transistors of circuit 300. Bias sub-circuit 305 may include transistor 326, transistor 327, and transistor 328 that each include a gate terminal, a source terminal, and a drain terminal. The drain terminal of transistor 326 may be coupled to receive bias current 325 from power supply 302 and may be coupled to the gate terminal of transistor 326, the gate terminal of transistor 328, and to a first set of transistors of circuit 300, such as transistors 350, 351, and 352. The source terminal of transistor 326 may be coupled to ground node 333. The source terminal of transistor 327 may also be coupled to power supply 302 and to a second set of transistors of circuit 300, such as transistors 329, 330, and 331. The gate terminal of transistor 327 may be coupled to the drain terminal of transistor 327 and to the second set of transistors of circuit 300. More specifically, the gate terminal of transistor 327 may be coupled to provide a voltage bias to gate terminals of transistors of transistors 329, 330, and 331. The drain terminal of transistor 327 may be coupled to the drain terminal of transistor 328. The source terminal of transistor 328 may be coupled to ground node 334.

A first transistor of the first set of transistors, a second transistor of the second set of transistors, and a subset of the set of switches of circuit 300 form an arm of circuit 300. Circuit 300 may include n arms, each of which may include first switches coupled to provide signals to a first output 357 and second switches coupled to provide signals to a second output 356. As illustrated in FIG. 3, circuit 300 includes three arms. A first arm includes transistor 329, switches 335, 336, 337, 338, and transistor 350. A second arm includes transistor 330, switches 340, 341, 342, and 343, and transistor 351. A third arm includes transistor 331, switches 345, 346, 347, and 348, and transistor 352. In other examples, fewer or additional numbers of arms may be included.

In the first arm, the source terminal of transistor 329 may be coupled to bias sub-circuit 305, to power supply 302, and to the source terminals of transistors 330 and 331. The gate terminal of transistor 329 may be coupled to the gate terminal of transistor 327. The drain terminal of transistor 329 may be coupled to first terminals of switches 335 and 337. A second terminal of switch 335 may be coupled to a first terminal of switch 336, which may both be coupled to output 357. A second terminal of switch 337 may be coupled to a first terminal of switch 338, which may both be coupled to output 356. The second terminals of switches 336 and 338 may be coupled together and to the drain terminal of transistor 350. In other words, switches 335 and 336 may be coupled together in series, switches 337 and 338 may be coupled together in series, and switches 335 and 336 may be coupled in parallel with respect to switches 337 and 338. The gate terminal of transistor 350 may be coupled to the gate terminal of transistor 326. The source terminal of transistor 350 may be coupled to ground node 353.

In the second arm, the source terminal of transistor 330 may be coupled to bias sub-circuit 305, to power supply 302, and to the source terminals of transistors 329 and 331. The gate terminal of transistor 330 may be coupled to the gate terminal of transistor 327. The drain terminal of transistor 330 may be coupled to first terminals of switches 340 and 342. A second terminal of switch 340 may be coupled to a first terminal of switch 341, which may both be coupled to output 357. A second terminal of switch 342 may be coupled to a first terminal of switch 343, which may both be coupled to output 356. The second terminals of switches 341 and 343 may be coupled together and to the drain terminal of transistor 351. In other words, switches 340 and 341 may be coupled together in series, switches 342 and 343 may be coupled together in series, and switches 340 and 341 may be coupled in parallel with respect to switches 342 and 343. The gate terminal of transistor 351 may be coupled to the gate terminal of transistor 326. The source terminal of transistor 351 may be coupled to ground node 354.

In the third arm, the source terminal of transistor 331 may be coupled to bias sub-circuit 305, to power supply 302, and to the source terminals of transistors 329 and 330. The gate terminal of transistor 331 may be coupled to the gate terminal of transistor 327. The drain terminal of transistor 331 may be coupled to first terminals of switches 345 and 347. A second terminal of switch 345 may be coupled to a first terminal of switch 3416, which may both be coupled to output 357. A second terminal of switch 347 may be coupled to a first terminal of switch 348, which may both be coupled to output 356. The second terminals of switches 346 and 348 may be coupled together and to the drain terminal of transistor 352. In other words, switches 345 and 346 may be coupled together in series, switches 347 and 348 may be coupled together in series, and switches 345 and 346 may be coupled in parallel with respect to switches 347 and 348. The gate terminal of transistor 352 may be coupled to the gate terminal of transistor 326. The source terminal of transistor 352 may be coupled to ground node 355.

Filter sub-circuit 360 may be representative of various hardware components coupled to receive signals from the switches of circuit 300 at outputs 356 and 357 and output analog output signals 370 and 371 at outputs of filter sub-circuit 360. Filter sub-circuit 360 may include operational amplifier 361, resistor 362, capacitor 363, resistor 364, and capacitor 365. Operational amplifier 361 includes two inputs and two outputs to produce differential analog outputs. A positive input of operational amplifier 361 is coupled to output 356 and to first terminals of resistor 362 and capacitor 363. A first output of operational amplifier 361 is coupled to second terminals of resistor 362 and capacitor 363 and coupled to output analog output signal 370. A negative input of operational amplifier 361 is coupled to output 357 and to first terminals of resistor 364 and capacitor 365. A second output of operational amplifier 361 is coupled to second terminals of resistor 364 and capacitor 365 and coupled to output analog output signal 371. Resistor 362 and capacitor 363 may be coupled together in parallel and may form a first resistor-capacitor (RC) circuit of filter sub-circuit 360. Resistor 364 and capacitor 365 may be coupled together in parallel and may form a second RC circuit of filter sub-circuit 360.

Decoder sub-circuit 310 may be representative of various components configured to receive digital input signals 301, decode the digital input signals 301, and provide control signals 313 and 314 to digital circuits 320 based on digital input signals 301. Decoder sub-circuit 310 includes decoder 311, which may include 1-bit adder 312. Decoder 310 receives digital signals 301 from a digital system or circuit. A subset of digital signals 301 may be provided to 1-bit adder 312, while another subset of digital signals 301 may be decoded by decoder 311 outside of 1-bit adder 312. The outputs of decoder 311 may be coupled to digital circuits 320. More specifically, a first output of decoder 311 may be coupled to provide control signals 313 to digital circuits 321, and a second output of decoder 311, or an output of 1-bit adder 312 thereof, may be coupled to provide control signals 314 to digital circuits 322.

Digital circuits 321 and 322 may include various circuits and devices coupled to receive control signals 313 and 314 from decoder sub-circuit 310 and coupled to control switches of circuit 300. For example, digital circuits 321 and 322 may include a number of flip-flop circuits, a number of level shifters, and a number of buffers. The flip-flop circuits of digital circuits 321 may be configured to store state data of the set of control signals 313, provide timing alignment among digital circuits 321, provide control signals 313 to the level shifters. The level shifters may be configured to increase or decrease a supply voltage, such as from a core supply voltage (e.g., 1.1 V) to an analog supply voltage (e.g., 1.3 V). The buffers may be configured to output control signals 313 to first switches of circuit 300 (e.g., switches 335 and 336, switches 340 and 341, and switches 345 and 346) for control thereof. The number of flip-flop circuits, level shifters, and buffers of digital circuits 320 may be based on the number of arms of DAC sub-circuit 120. The flip-flop circuits of digital circuits 322 may be configured to store state data of control signals 314, provide timing alignment among digital circuits 322, provide control signals 314 to the level shifters. The level shifters may be configured to increase or decrease a supply voltage, such as from a core supply voltage (e.g., 1.1 V) to an analog supply voltage (e.g., 1.3 V). The buffers may be configured to output control signals 314 to second switches of circuit 300 (e.g., switches 337 and 338, switches 342 and 343, and switches 347 and 348) for control thereof. In various examples, digital circuits 322 may include one flip-flop circuit, level shifter, and buffer based on the topology of circuit 300.

In various examples, the first set of digital input signals may include signals from n-1 to 0, where n is the number of arms of circuit 300. In an example where n is equal to 7, such as the example illustrated in FIG. 7, decoder may receive 7 digital signals, B<6>, B<5>, B<4>, B<3>, B<2>, B<1>, and B<0>. B<6> may be representative of a direction control signal, and the other digital input signals may be used to control switches of circuit 300. More specifically, decoder 311 may receive a first subset of digital input signals 301 that includes B<5>, B<4>, B<3>, B<2>, B<1> at an input of decoder 311 and at an input of 1-bit adder 312. Decoder 311 may decode the first subset of digital input signals 301 and output positive control signals 313 that includes P<4:0>. These control signal 313 may be used to control those switches coupled to output 356 (e.g., switches 337, 338, 342, 342, 347 and/or 348). 1-bit adder 312 may also receive B<0> in addition to the first subset of digital input signals 301, decode the digital input signals 301, and output negative control signals 314 that includes M<4:0>. These control signal 314 may be used to control those switches coupled to output 357 (e.g., switches 335, 336, 340, 341, 345 and/or 346). In this way, 1-bit adder 312 may add an extra resolution bit to digital input signals 301 for use by digital circuits 320. Next, digital circuits 321 may receive control signals 313, and digital circuits 322 may receive control signals 314. As explained above, digital circuits 321 may use control signals 313 to control the first switches of circuit 300, and digital circuits 322 may use control signals 314 to control the second switches of circuit 300.

Based on being controlled by digital circuits 321 and 322, the switches of circuit 300 may provide differential signals at outputs 356 and 357. More specifically, the first switches may provide positive signals at output 357 based on the positive control signals 313, and the second switches may provide negative signals at output 356 based on the negative control signals 314. Filter sub-circuit 360 can receive the differential signals at outputs 356 and 357 and performs comparisons, via operational amplifier 361 and the two RC circuits of filter sub-circuit 360, on the differential signals to determine analog output signals 370 and 371.

In an example, in a first mode of operation, the least significant bit of the digital value (B<0>) is set to zero, and the decoder 310 determines control signals 313 and 314 based on bits B<1> through B<5>. In a second mode of operation, the decoder 310 determines control signals 313 based on bits B<1> through B<5> and control signals 314 based on the sum of bit B<0> and bits B<1> through B<5>.

While some examples provided herein are described in the context of an integrated circuit, a system-on-chip (SoC), a digital-to-analog converter (DAC), a sub-circuit, a subsystem, a component, a device, an architecture, or an environment, the circuits, devices, gates, latches, flip-flops, logic elements, and other circuits, systems, and methods described herein are not limited to such embodiments and may apply to a variety of other processes, systems, applications, devices, and the like, such as other circuits, logic devices, latches, transistors, and the like, in the context of increasing transistor resolution efficiency, among other benefits, for example. Accordingly, aspects of the present invention may be embodied as other systems, methods, and other configurable systems.

Unless the context clearly requires otherwise, throughout the description and the claims, the words "comprise," "comprising," and the like are to be construed in an inclusive sense, as opposed to an exclusive or exhaustive sense; that is to say, in the sense of "including, but not limited to." As used herein, the terms "connected," "coupled," or any variant thereof means any connection or coupling, either direct or indirect, between two or more elements; the coupling or connection between the elements can be physical, logical, or a combination thereof. Additionally, the words "herein," "above," "below," and words of similar import, when used in this application, refer to this application as a whole and not to any particular portions of this application. Where the context permits, words in the above Detailed Description using the singular or plural number may also include the plural or singular number respectively. The word "or," in reference to a list of two or more items, covers all of the following interpretations of the word: any of the items in the list, all of the items in the list, and any combination of the items in the list.

The phrases "in some embodiments," "according to some embodiments," "in the embodiments shown," "in other embodiments," and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words "means for” but use of the term "for" in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A circuit, comprising:
a first digital-to-analog converter (DAC) sub-circuit that comprises:
a first transistor coupled to a power supply node;
a first switch coupled to the first transistor and to a first output node;
a second switch coupled to the first transistor and to a second output node;
a second transistor coupled to the power supply node;
a third switch coupled to the second transistor and to the first output node;
a fourth switch coupled to the second transistor and to the second output node;
a second DAC sub-circuit coupled to the first DAC sub-circuit that comprises:
a third transistor coupled to the power supply node;
a fifth switch coupled to the third transistor and coupled to the first output node;
a sixth switch coupled to the third transistor and coupled to the second output node;
a fourth transistor coupled to the power supply node;
a seventh switch coupled to the fourth transistor and to the first output node; and
an eighth switch coupled to the fourth transistor and to a ground node; and
a control circuit coupled to control the switches of the first DAC sub-circuit and the second DAC sub-circuit.

2. The circuit of claim 1, wherein:
the first DAC sub-circuit further comprises:
a fifth transistor coupled to the first transistor; and
a sixth transistor coupled to the second transistor; and
the second DAC sub-circuit further comprises a seventh transistor coupled to the power supply node and to the first DAC sub-circuit.

3. The circuit of claim 1, wherein the control circuit comprises:
a set of decoders coupled to receive a set of digital signals; and
a set of driver circuits coupled to the set of decoders and coupled to control the switches of the first DAC sub-circuit and the second DAC sub-circuit;
wherein the set of decoders includes:
a first decoder coupled to receive a first subset of digital signals of the set of digital signals; and
a second decoder coupled to receive a second subset of digital signals of the set of digital signals; and
wherein the set of driver circuits includes:
a first driver circuit coupled to receive the first subset of digital signals from the first decoder and coupled to provide the first subset of digital signals to the switches of the first DAC sub-circuit;
a second driver circuit coupled to receive the second subset of digital signals from the second decoder and coupled to provide the second subset of digital signals to the fifth, sixth, and seventh switches of the second DAC sub-circuit; and
a third driver circuit coupled to receive a third subset of digital signals and coupled to provide the third subset of digital signals to the eighth switch of the second DAC sub-circuit.

4. The circuit of claim 3, wherein the first, second, and third driver circuits comprise one or more flip-flop circuits, one or more level shifter circuits, one or more buffer circuits, and one or more logic gates.

5. The circuit of claim 4, further comprising a bias sub-circuit coupled to receive a supply power and a filter sub-circuit coupled to the first output node and to the second output node, wherein the filter sub-circuit comprises:
an operational amplifier circuit, including:
a first input coupled to the first output node;
a second input coupled to the second output node;
a first output; and
a second output;
a first resistor-capacitor circuit coupled to the first output node, the first input, and the first output; and
a second resistor-capacitor circuit coupled to the second output node, the second input, and the second output.

6. The circuit of claim 5, wherein:
the first resistor-capacitor circuit comprises a first resistor having a first terminal and a second terminal and a first capacitor having a first terminal and a second terminal;
the second resistor-capacitor circuit comprises a second resistor having a first terminal and a second terminal and a second capacitor having a first terminal and a second terminal;
the first terminal of the first resistor is coupled to the first terminal of the first capacitor, to the first output node, and to the first input;
the second terminal of the first resistor is coupled to the second terminal of the first capacitor and to the first output;
the first terminal of the second resistor is coupled to the first terminal of the second capacitor, to the second output node, and to the second input; and
the second terminal of the second resistor is coupled to the second terminal of the second capacitor and to the second output.

7. The circuit of claim 6, wherein the operational amplifier circuit is configured to receive input signals, based on the set of digital signals, from the switches of the first and second DAC sub-circuits, convert the input signals to analog signals, and provide the analog signals at the first output and the second output.

8. A circuit, comprising:
a set of driver circuits coupled to receive a set of digital signals;
a first digital-to-analog converter (DAC) sub-circuit coupled to a first subset of the set of driver circuits;
a second DAC sub-circuit coupled to the first DAC sub-circuit and coupled to a second subset of the set of driver circuits; and
a third DAC sub-circuit coupled to the first DAC sub-circuit, to the second DAC sub-circuit, and coupled to a third subset of the set of driver circuits;
wherein the first DAC sub-circuit comprises a first set of transistors and a first set of switches coupled to the first set of transistors;
wherein the second DAC sub-circuit comprises a second set of transistors and a second set of switches coupled to the second set of transistors;
wherein the third DAC sub-circuit comprises a transistor, a first switch coupled to the transistor, and a second switch coupled to the transistor;
wherein the first subset of the set of digital circuits comprises a first decoder coupled to receive a first subset of the set of digital signals and is configured to provide the first subset of the set of digital signals to the first set of switches;
wherein the second subset of the set of digital circuits comprises a second decoder coupled to receive a second subset of the set of digital signals and is configured to provide the second subset of the set of digital signals to the second set of switches; and
wherein the third subset of the set of digital circuits is coupled to receive a third subset of the set of digital signals and is configured to provide the third subset of the set of digital signals to first switch of the third DAC sub-circuit; and
wherein the first, second, and third DAC sub-circuits are configured to output signals, based on the first, second, and third subsets of the digital signals, respectively, at a first output node and at a second output node.

9. The circuit of claim 8, further comprising a bias sub-circuit coupled to receive a supply power.

10. The circuit of claim 9, wherein:
the first set of transistors comprises:
a first transistor coupled to the bias sub-circuit;
a second transistor coupled to the first transistor;
a third transistor coupled to the bias sub-circuit;
a fourth transistor coupled to the third transistor; and
a fifth transistor coupled to the bias sub-circuit;
the first set of switches comprises:
a first switch coupled to the second transistor and to the first output node; and
a second switch coupled to the second transistor and to the second output node;
a third switch coupled to the third transistor and to the first output node;
a fourth switch coupled to the third transistor and to the second output node;
the second set of transistors comprises a sixth transistor coupled to the fifth transistor of the first set of transistors;
the second set of switches comprises:
a fifth switch coupled to the sixth transistor and coupled to the first output node; and
a sixth switch coupled to the sixth transistor and coupled to the second output node;
the transistor is coupled to the fifth transistor of the first set of transistors;
the first switch of the third DAC sub-circuit is coupled to the transistor and to the first output node;
the second switch of the third DAC sub-circuit is coupled to the transistor and to a ground node; and
the set of driver circuits is coupled to control the switches.

11. The circuit of claim 10, wherein the set of driver circuits further comprises a set of control circuits that include:
a first control circuit coupled to receive the first subset of digital signals from the first decoder and coupled to provide the first subset of digital signals to the first set of switches;
a second control circuit coupled to receive the second subset of digital signals from the second decoder and coupled to provide the second subset of digital signals to the fifth, sixth, and seventh switches of the second set of switches; and
a third control circuit coupled to receive a third subset of digital signals and coupled to provide the third subset of digital signals to the first switch of the third DAC sub-circuit.

12. The circuit of claim 11, wherein the first, second, and third control circuits comprise one or more flip-flop circuits, one or more level shifter circuits, one or more buffer circuits, and one or more logic gates.

13. The circuit of claim 8, further comprising a filter sub-circuit coupled to the first output node and to the second output node, wherein the filter sub-circuit comprises:
an operational amplifier circuit, including:
a first input coupled to the first output node;
a second input coupled to the second output node;
a first output; and
a second output;
a first resistor-capacitor circuit coupled to the first output node, the first input, and the first output; and
a second resistor-capacitor circuit coupled to the second output node, the second input, and the second output.

14. The circuit of claim 13, wherein:
the first resistor-capacitor circuit comprises a first resistor having a first terminal and a second terminal and a first capacitor having a first terminal and a second terminal;
the second resistor-capacitor circuit comprises a second resistor having a first terminal and a second terminal and a second capacitor having a first terminal and a second terminal;
the first terminal of the first resistor is coupled to the first terminal of the first capacitor, to the first output node, and to the first input;
the second terminal of the first resistor is coupled to the second terminal of the first capacitor and to the first output;
the first terminal of the second resistor is coupled to the first terminal of the second capacitor, to the second output node, and to the second input; and
the second terminal of the second resistor is coupled to the second terminal of the second capacitor and to the second output.

15. The circuit of claim 14, wherein the operational amplifier circuit is configured to receive the output signals, based on the set of digital signals, from respective switches, convert the input signals to analog signals, and provide the analog signals at the first output and the second output.

16. A circuit, comprising:
a first digital-to-analog converter (DAC) sub-circuit, wherein the first DAC sub-circuit comprises:
a first transistor coupled to a power supply;
a second transistor coupled to a first ground node;
a first switch coupled to the first transistor;
a second switch coupled to the first switch and to the second transistor;
a third switch coupled to the first transistor;
a fourth switch coupled to the third switch and to the second transistor;
a third transistor coupled to the power supply;
a fourth transistor coupled to a second ground node;
a fifth switch coupled to the third transistor;
a sixth switch coupled to the fifth switch and to the fourth transistor;
a seventh switch coupled to the third transistor; and
an eighth switch coupled to the seventh switch and to the fourth transistor;
a second DAC sub-circuit coupled to the first DAC sub-circuit, wherein the second DAC sub-circuit comprises:
a fifth transistor coupled to the first DAC sub-circuit and to the power supply;
a sixth transistor coupled to a third ground node;
a ninth switch coupled to the fifth transistor;
a tenth switch coupled to the ninth switch and to the sixth transistor;
an eleventh switch coupled to the fifth transistor; and
a twelfth switch coupled to the eleventh switch and to the sixth transistor; and
a set of driver circuits coupled to control the switches of the first DAC sub-circuit and the second DAC sub-circuit;
wherein the first and second switches, the fifth and sixth switches, and the ninth and tenth switches are coupled to a first output node; and
wherein the third and fourth switches, the seventh and eighth switches, and the eleventh and twelfth switches are coupled to a second output node.

17. The circuit of claim 16, further comprising a bias sub-circuit coupled to the power supply and coupled to the first and second DAC sub-circuits.

18. The circuit of claim 16, wherein the set of driver circuits comprise:
a decoder coupled to receive a set of digital signals; and
a set of control circuits coupled to the set of decoders and coupled to control the switches of the first and second DAC sub-circuits;
wherein the decoder includes:
a first data path coupled to receive a first subset of digital signals of the set of digital signals; and
a second data path comprising a one-bit adder coupled to receive a second subset of digital signals of the set of digital signals; and
wherein the set of control circuits includes:
a first control circuit coupled to receive the first subset of digital signals from the decoder via the first data path and coupled to provide the first subset of digital signals to the first and second switches, the fifth and sixth switches, and the ninth and tenth switches; and
a second control circuit coupled to receive the second subset of digital signals from the one-bit adder of the decoder via the second data path and coupled to provide the second subset of digital signals to the third and fourth switches, the seventh and eighth switches, and the eleventh and twelfth switches.

19. The circuit of claim 18, wherein the first and second control circuits comprise one or more flip-flop circuits, one or more level shifter circuits, one or more buffer circuits, and one or more logic gates.

20. The circuit of claim 16, further comprising a filter sub-circuit coupled to the first output node and to the second output node, wherein:
the filter sub-circuit comprises:
an operational amplifier circuit, including:
a first input coupled to the first output node;
a second input coupled to the second output node;
a first output; and
a second output;
a first resistor-capacitor circuit coupled to the first output node, the first input, and the first output; and
a second resistor-capacitor circuit coupled to the second output node, the second input, and the second output; and
the filter sub-circuit is configured to:
receive input signals, based on the set of digital signals, from respective switches at the first output node and the second output node;
convert the input signals to analog signals; and
provide the analog signals at the first output and the second output.
